(19) United States
(12) Patent Application Publication
(10) Pub. No.: US 2006/0076850 A1
(43) Pub. Date: Apr. 13, 2006

(54) Surface acoustic wave device and its fabrication method

(76) Inventors: Hui-Ling Kao, Jungli City (TW); Sheng-Wen Chen, Kaohsiung City (TW); Jyh-Shin Chen, Hsinchu City (TW)

Correspondence Address: HDSL, 4331 STEVENS BATTLE LANE, FAIRFAX, VA, 22033, US

(21) Appl. No.: 10/959,980

(22) Filed: Oct. 8, 2004

(51) Int. Cl. H03H 9/25

(52) U.S. Cl. 310/313 R

(57) ABSTRACT

A thin film layered surface acoustic wave device includes a substrate, a GaN piezoelectric film, an AlN piezoelectric film and interdigital transducer electrodes. The GaN piezoelectric film is deposited on the substrate by chemical vapor deposition (CVD) or physical vapor deposition (PVD) method. Then the AlN piezoelectric film is deposited on top surface of the GaN piezoelectric film by the same way. Finally, the interdigital transducer electrodes are deposited on top surface of AlN piezoelectric film and form by etching of lift off method. Accordingly, high operating frequency and low loss surface acoustic wave devices can be produced which can be integrated with high frequency devices, such as HBT and HEMT, and different devices.

### BACKGROUND OF THE INVENTION

1. Field of the Invention

This invention concerns a kind of thin film layered surface acoustic wave (SAW) device and its fabrication method. It features the use of two different piezoelectric thin films. The combination of these two films for surface acoustic wave devices may bring about the development of future components for high frequency signal processing, and high power devices which integrate and utilize their piezoelectric, semiconducting and optoelectronic properties.

2. Description of the Related Art

Surface acoustic wave devices have been widely applied in televisions, videotape recorders and other electronic products. Presently surface acoustic wave devices even play important roles in high frequency wireless communication industry. However, most of the current surface acoustic wave devices are made of bulk piezoelectric crystals such as LiNbO₃ and quartz. To fabricate high frequency, low cost, small sized and lightweight surface acoustic wave devices, and to integrate surface acoustic wave devices with other electronic devices, new piezoelectric thin films with high surface acoustic velocity are very important.

The investigated piezoelectric thin films are AlN, ZnO, GaN etc, for their excellent piezoelectricity, high surface acoustic wave velocity, and substantial electromechanical coupling coefficient. The high acoustic velocity of the piezoelectric films can relieve the sub-micron process in the development of SAW devices operating at high frequency in wireless communication technology. III-nitride materials, especially AlN and GaN, are attractive for optoelectronic and high power, high temperature device applications. In addition, these materials are also uniquely suited for high temperature piezoelectrics, pyroelectric sensors, and surface acoustic wave devices, due to strong lattice polarization effects. GaN is a newly introduced material for SAW devices. It is a semiconductor with piezoelectric properties and its production skill is established to the level of commercial needs. It can be used in hybrid optoelectronic devices for the applications of acousto-optic and piezoelectric devices. However, realizing good SAW devices on epitaxial GaN was usually obstructed by the relatively high electrical conductivity of GaN, which is caused by the residual donors during the growth, the introduced doping for devices fabrication and the relatively small energy band gap. In this work, we proposed to deposit AlN films on epitaxial GaN films using low temperature process of helicon sputtering method. SAW devices fabricated on AlN/GaN/sapphire and GaN/sapphire were investigated. AlN had been known to have high acoustic velocity and substantial electromechanical coupling coefficient among piezoelectric materials. The composite structure of AlN on GaN film can lessen the intrinsic problems of SAW made on GaN/sapphire, and enhance the piezoelectric properties, due to the lower electrical conductivity and larger piezoelectric coefficient of AlN than those of GaN.

### SUMMARY OF THE INVENTION

The present invention is to provide a thin film layered surface acoustic wave (SAW) device and its fabrication method. It features the use of two different piezoelectric thin films, AlN/GaN, on a substrate. Electrodes of interdigital transducer were deposited on AlN/GaN layer to form a filter.

Based on the larger piezoelectric coefficient and the lower electrical conductivity of AlN/GaN, we can produce high operating frequency and low insertion loss SAW devices, and integrate the SAW devices with other electronic devices, such as HBT, HEMT.

This invention comprises a substrate, a GaN film, an AlN film and interdigital electrodes. We deposit the GaN film on the substrate, and then deposit the AlN film on GaN film to form AlN/GaN/substrate structure. Finally, we deposit Al metal film on AlN/GaN/substrate and fabricate electrodes of interdigital transducers by means of etching or lift off method. Thus, a thin film layered structure surface acoustic wave device is fabricated. The deposition can be operated by chemical vapor deposition (CVD) or physical vapor deposition (PVD) process.

### BRIEF DESCRIPTION OF THE DRAWINGS

These features and advantages of the present invention will be fully understood and appreciated from the following detailed description of the accompanying Drawings.

FIG. 1 is a top view diagram of the thin film layered surface acoustic wave device of the present invention;

FIG. 2A to 2C are flow charts of fabricating he thin film layered surface acoustic wave device of the present invention; and

FIGS. 3A and 3B are frequency responses of the surface acoustic wave devices for comparison.

### DETAILED DESCRIPTION OF THE PREFERRED EMBODIMENT

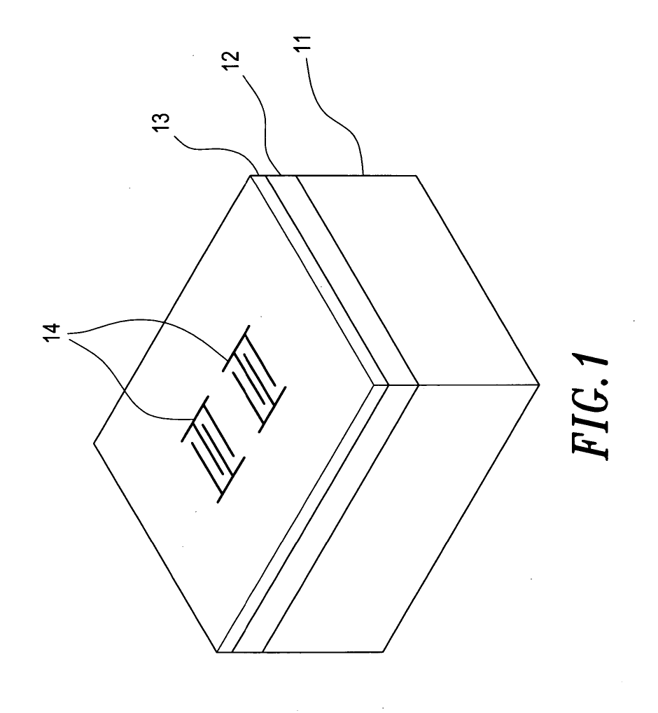

Please refer to FIG. 1, the thin film layered surface acoustic wave device includes a substrate 11, a GaN piezoelectric filem 12, an AlN piezoelectric film 13, and at least one electrode of interdigital transducer 14.

The substrate 11 can be made of sapphire, quartz, silicon or others.

The GaN piezoelectric film 12 can be deposited on the substrate 11 by physical or chemical deposition method.

The AlN piezoelectric film 13 can be deposited on the GaN piezoelectric film 12 by physical or chemical deposition method.

The interdigital transducer 14 can be deposited on the AlN piezoelectric film 13 by physical or chemical deposition method, or formed by etching or lift off method.

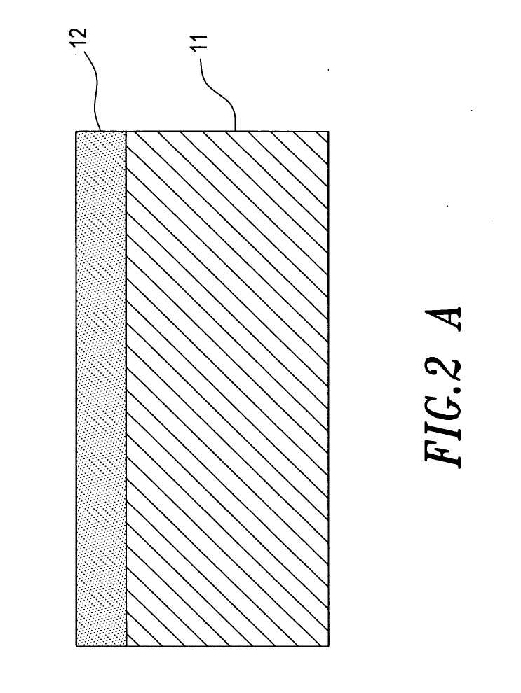

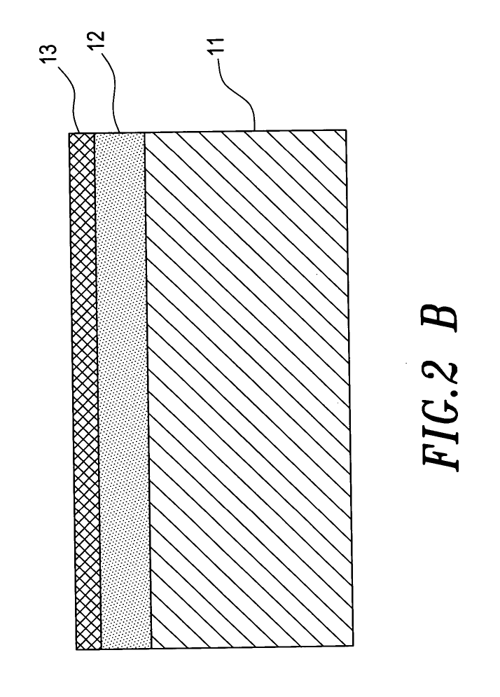

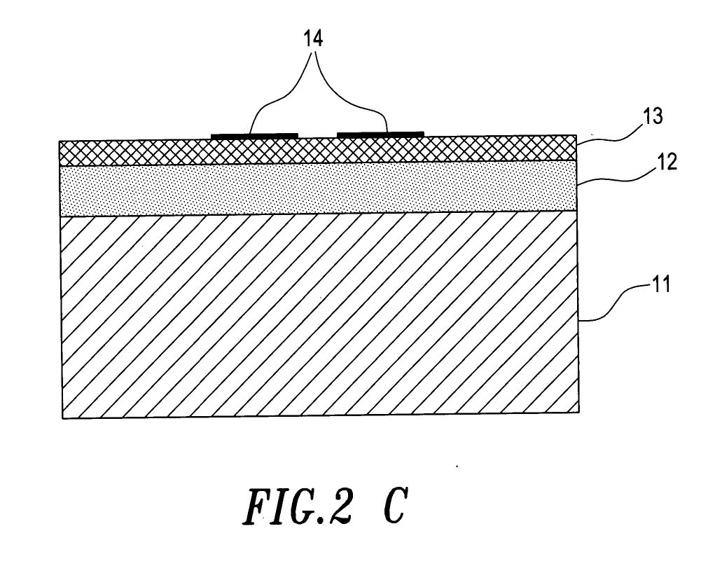

Additionally, please refer to FIGS. 2A, 2B and 2C, which show the steps of the method for fabricating the thin film layered surface acoustic wave device as follows.

Step 1. A GaN piezoelectric film 12 is deposited on the top surface of a substrate 11 (as shown in FIG. 2A).

Step 2. Further, an AlN piezoelectric film 13 is deposited on the top surface of GaN piezoelectric film 12 (as shown in FIG. 2B)

Step 3. Finally, at least one interdigital transducer electrode 14 is deposited on the suitable position of top surface of AlN piezoelectric film 13 (as shown in FIG. 2C).

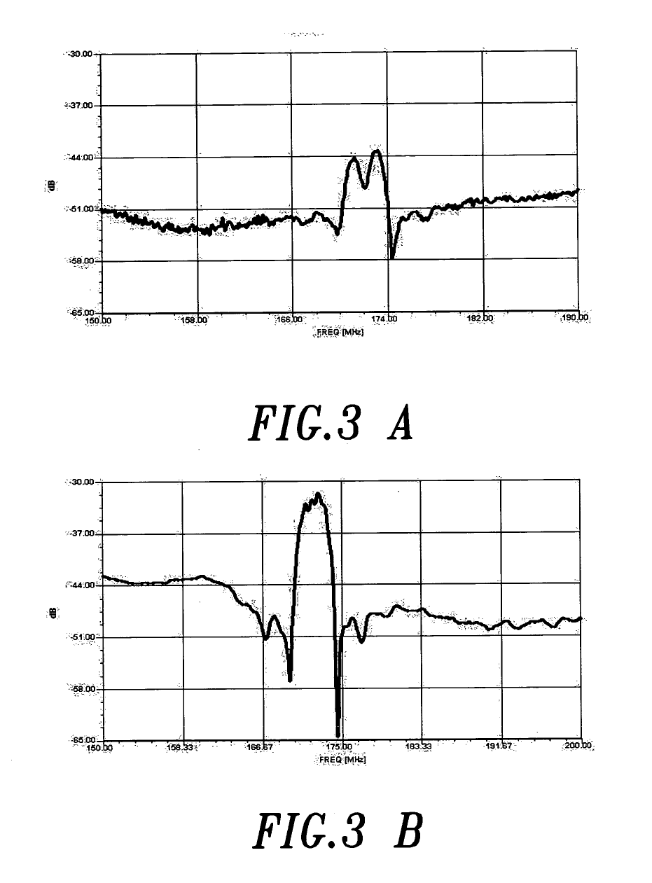

Please refer to FIGS. 3A and 3B, which show the frequency response diagrams of surface acoustic wave devices for comparison. FIG. 3A shows the frequency response of a surface acoustic wave device fabricated a GaN piezoelectric film on a sapphire substrate. FIG. 3B shows the frequency response of another surface acoustic wave device made an AlN/GaN piezoelectric film on a sapphire substrate. As shown from the figures, the response and filter effect of the device fabricated on AlN/GaN piezoelectric film is better.

By fabricating every component mentioned above, the insertion loss can be reduced greatly. And the excellent piezoelectricity of the fabrication can be used to manufacture high operating frequency and low loss SAW devices. This SAW device can be integrated with high frequency and/or high power devices.

The thin film layered surface acoustic wave device and its fabrication method supplied by this invention embrace the following advantages as compared with the prior art:

This invention provides a use of two different piezoelectric materials. Coordinate the advantages of these two materials and combine them with interdigital transducer electrodes to achieve the effect of integrating capability.

This invention provides a thin film layered surface acoustic wave device and its fabrication method to reduce the insertion loss. By using its excellent piezoelectricity, high operating frequency and low loss surface acoustic wave devices can be fabricated and can be integrated with high frequency and/or high power devices and different devices progressively. It will be hopeful for the present invention to be more competitive.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A thin film layered surface acoustic wave device comprising:
a substrate;
a GaN piezoelectric film deposited on the substrate;
an AlN piezoelectric film deposited on the GaN piezoelectric film; and
at least one interdigital transducer electrode deposited on the AlN piezoelectric film.

2. Thin film layered surface acoustic wave device according to claim 1,
wherein the substrate is made of sapphire, quartz or silicon.

3. A method for fabricating a thin film layered surface acoustic wave
device comprising the steps of:
depositing a GaN piezoelectric film on a substrate;
depositing an AlN piezoelectric film on the GaN piezoelectric film;
depositing at least one interdigital transducer electrode on a predetermined position of the AlN piezoelectric film.

4. The method according to claim 3, wherein the GaN piezoelectric film is deposited on substrate by a physical or a chemical deposition.

5. The method according to claim 3, wherein the AlN piezoelectric film is deposited on the GaN piezoelectric film by a physical or a chemical deposition.

6. The method according to claim 3, wherein the interdigital transducer electrode is deposited on the AIN piezoelectric film by a physical or chemical a deposition.

7. The method according to claim 3, wherein the interdigital transducer electrode is formed by etching or lift off.
